(19) United States
(12) Patent Application Publication
(10) Pub. No.: US 2011/0147827 A1
(43) Pub. Date: Jun. 23, 2011

(54) Flash memory with partially removed blocking dielectric in the wordline direction

(76) Inventors: Fatma Arzum Simsek-Ege, Boise, ID (US); Sanh Tang, Boise, ID (US); Nirmal Ramaswamy, Boise, ID (US); Thomas M. Graettinger, Boise, ID (US); Kyu S. Min, San Jose, CA (US); Tejas Krishnamohan, Mountain View, CA (US); Srivardhan Gowda, Boise, ID (US)

(21) Appl. No.: 12/655,090

(22) Filed: Dec. 23, 2009

(51) Int. Cl. H01L 29/792

(52) U.S. Cl. 257/326; 257/E29.309

(57) ABSTRACT

The present disclosure relates generally to the fabrication of non-volatile memory. In at least one embodiment, the present disclosure relates to forming a layered blocking dielectric which has a portion thereof removed in the wordline direction.

### BACKGROUND OF THE INVENTION

The present disclosure relates generally to the fabrication of non-volatile memory. In at least one embodiment, the present disclosure relates to forming a layered blocking dielectric which has a portion thereof removed in the wordline direction.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, and in which:

FIG. 1 is a circuit schematic of a NAND flash memory array;

FIG. 2 is a side cross-sectional view of the flash memory cell in the bitline direction;

FIGS. 3a-3g are side cross-sectional views of an embodiment of fabricating a memory cell in the wordline direction;

FIGS. 4a and 4b are side cross-sectional views of an embodiment of fabricating a memory cell in the wordline direction;

FIGS. 5a-5f are side cross-sectional views of an embodiment of fabricating a memory cell in the wordline direction;

FIGS. 6a-6d are side cross-sectional views of an embodiment of fabricating a memory cell in the wordline direction;

FIG. 7 is a block diagram of an embodiment process of fabrication a memory cell;

FIG. 8 illustrates an embodiment of a portable electronic device;

FIG. 9 illustrates an embodiment of a computer system; and

FIG. 10 is a block diagram of an electronic system.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

Embodiments of the present description relate to the field of flash memory fabrication. In at least one embodiment of the present disclosure, memory cells are fabricated which include forming a multilayer blocking dielectric that has at least a portion thereof removed in the wordline direction.

Memory devices are integrated circuits that provide data storage of electronics devices, including volatile memory which loses stored information when not powered (e.g., RAM—Random Access Memory) and non-volatile memory which retain stored information even when not powered (e.g., flash memory). Non-volatile flash memory is generally used in portable devices, such as cellular telephones, personal digital assistants (“PDA”), portable digital media players, digital cameras, solid state computer hard drives, and the like.

Flash memory generally includes a plurality of memory cells, which are floating-gate transistors. The memory cells are typically stacked gated structures comprising a flowing gate, which is electrically isolated from an underlying semiconductor substrate by a thin dielectric layer (referred to as a “tunnel dielectric”), and a control gate positioned which above the floating gate and electrically isolated therefrom by an inter-poly dielectric layer. The inter-poly dielectric may be a layered structure comprising a silicon nitride layer between two layers of silicon oxide (referred to in the industry as an “ONO” or “Oxide-Nitride-Oxide” layer).

The floating gate is generally a conductive material that serves as a charge storage element for storing an electrical charge. This charge storage defines the memory state of that transistor, wherein the presence or lack of a stored charge represents a binary “1” or “0” state in one data bit. The floating gate, typically composed of polycrystalline silicon (i.e., referred to in the industry as “polysilicon”). The floating gate is “floating” in the sense that the bottom of the floating gate is insulated by the tunnel dielectric, and the top of the floating gate is insulated by the inter-poly dielectric layer.

In many instances, the interfacing area between the floating gate and the tunnel dielectric is smaller than the interfacing area between the floating gate and the top gate (“control gate”). The asymmetry is often created by the control gate that “wraps around” the upper portions of the floating gate over the control dielectric. This asymmetric area ratio may give rise to an advantage in a key capacitive coupling parameter called the “gate coupling ratio” compared to not have the asymmetry. The increased gate coupling ratio may give rise to many device advantages including lower program voltage, lower gate leakage, and the like.

The flash memory industry has continuously strived to reduce the size of their memory product, which has generally resulted in faster and less expensive memory products. However, as flash memory has scaled below about 40 nm node (measured as the bitline-to-bitline half-pitch), several major challenges may arise due to bitlines and wordlines getting too close to one another. Due to shrinking physical dimensions, it may become impractical to maintain the advantageous asymmetry in area ratios traditionally achieved through “wrapping” of the control gate. The effective elimination of the “wrap” effect, which renders all cells “planar” at the sub-40 nm node, may result in a rapid degradation of the gate coupling ratio. The reduction of the gate coupling ratio, in turn, may lead to detrimental parasitic coupling between neighboring cells, as well as program/erase voltage saturation, as will be understood to those skilled in the art.

One method to mitigate the reduction in capacitive-coupling ratio is through the reduction of the inter-poly dielectric layer effective oxide thickness by replacing the inter-poly dielectric layer with a high K (high dielectric constant) dielectric material, referred to as a high K blocking dielectric. The use of a high K blocking dielectric may allow the cell to, at least partially, gain back the reduced capacitive-coupling ratio, while maintaining a relatively high physical thickness to prevent excessive leakage during read, program, or erase operations. However, the combination of a “planar” cell with a high K blocking dielectric as the inter-poly dielectric layer is only a partial solution due to some key tradeoffs including lateral charge loss arising from charge transfer through the high K blocking dielectric (or related interfaces if the layered high K blocking dielectric used), and parasitic cell-to-cell capacitive coupling which may lead to interference effects during a read operation.

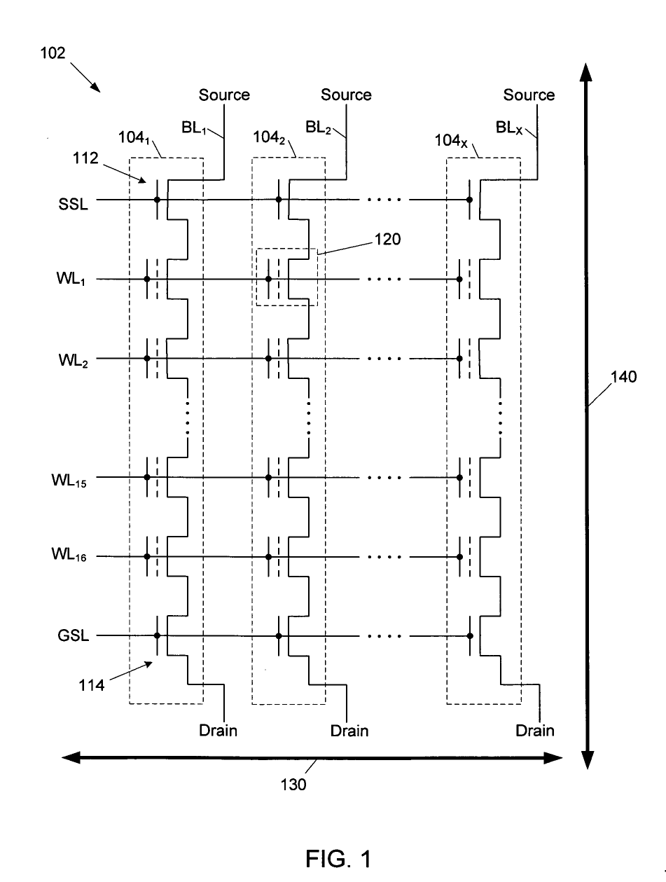

FIG. 1 is a circuit diagram illustrating a NAND flash memory circuit. The NAND flash memory circuit includes a memory cell array 102 which is composed of a number of flash memory cell strings 104₁, 104₂, . . . , and 104_{X} connected to respective bitlines, BL₁, BL₂, . . . , and BL_{X}. While FIG. 1 illustrates three cell strings for convenience, it is understood that there may be any number of flash memory cell strings (represent as “x”) within the memory cell array 102 in accordance with the dimension of a desired NAND flash memory device.

Each flash memory cell string 104₁, 104₂, . . . , and 104_{X} includes a string selection transistor gate 112, a ground selection transistor gate 114, and a number of flash memory cells 120 connected in series between the string selection transistor gate 112 and the ground selection transistor gate 114. The string selection transistor gate 112, the ground selection transistor gate 114, and flash memory cells 120 of each string are coupled to a string selection line SSL, wordlines WL₁, WL₂, . . . , WL₁₅, and WL₁₆, and a ground selection line GSL, respectively. The string selection line SSL, wordlines WL₁, WL₂, . . . , WL₁₅, and WL₁₆, and a ground selection line GSL carry outputs from a row decoder (not shown). The wordline direction of the memory cell array 102 is defined by arrow 130 and the bitline direction of the memory cell array 102 is defined by arrow 140.

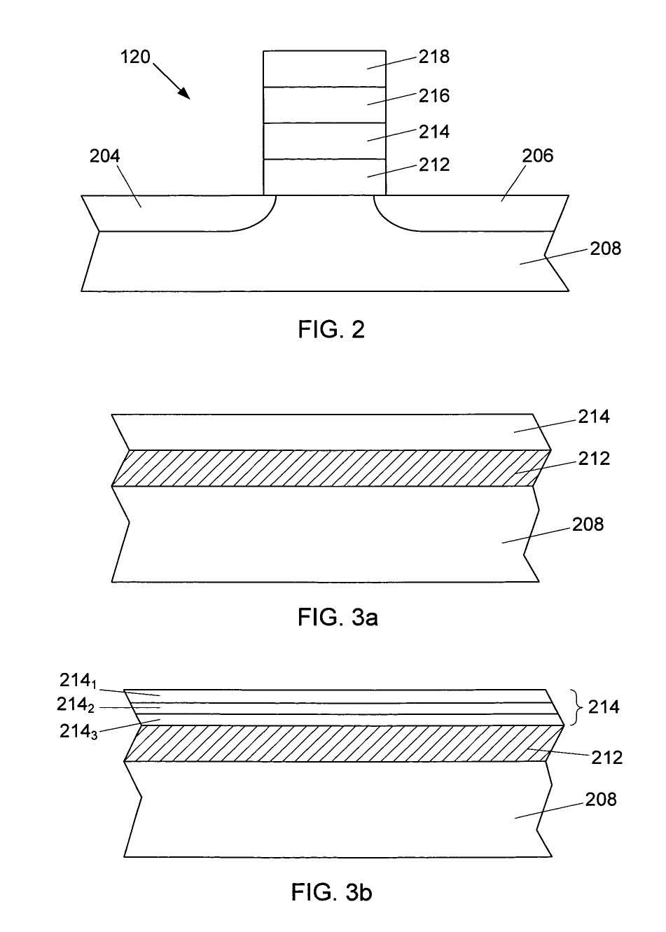

FIG. 2 illustrates a side cross-sectional view of the flash memory cell 120 in the bitline direction 140 (see FIG. 1). The flash memory cell 120 may be disposed between a doped source region 204 and a doped drain region 206. The doped source region 204 and a doped drain region 206 may be formed by implanting a dopant into a microelectronic substrate 208, as will be understood to those skilled in the art. The flash memory cell 120 may comprise a tunnel dielectric layer 212 adjacent the microelectronic substrate 208, a charge storage layer 214 formed adjacent the tunnel dielectric layer 212, a multilayer blocking dielectric layer 216 (multiple layers not shown) formed adjacent the charge storage layer 214, and a control gate 218 formed adjacent the multilayer blocking dielectric layer 216.

In various embodiments, the multilayer blocking dielectric layer 216 may be comprised of two to five chemically distinct dielectric materials. It will be understood to those skilled in the art that the order of the layers will depend on the requirements of effective oxide thickness or other critical device parameters. It is, of course, understood that the stoichiometry of the compounds does not have to be exact, as some dielectric layers may be tuned out of stoichiometry for optimum performance.

In the fabrication of a NAND flash memory device, the charge storage layer 214 material must be removed between each adjacent memory cell 120 in each flash memory cell string 104₁, 104₂, . . . , and 104_{X} (i.e., in the bitline direction 140), if the charge storage layer 214 is composed of a conductive material. Even where the charge storage layer 214 is composed of discontinuous conductors or a continuous dielectric material, virtually all device architectures have the charge storage layer 214 and the multilayer blocking dielectric layer 216 removed between each adjacent memory cell 120 in each flash memory cell string 104₁, 104₂, . . . , and 104_{X}.

In the opposite direction between adjacent flash memory cell strings 104₁, 104₂, . . . , and 104_{X} (i.e., in the wordline direction 130), the charge storage layer 214 can remain without being removed, if the material used in forming the charge storage layer 214 is not a continuous conductor (i.e., a discontinuous conductor or a continuous dielectric material).

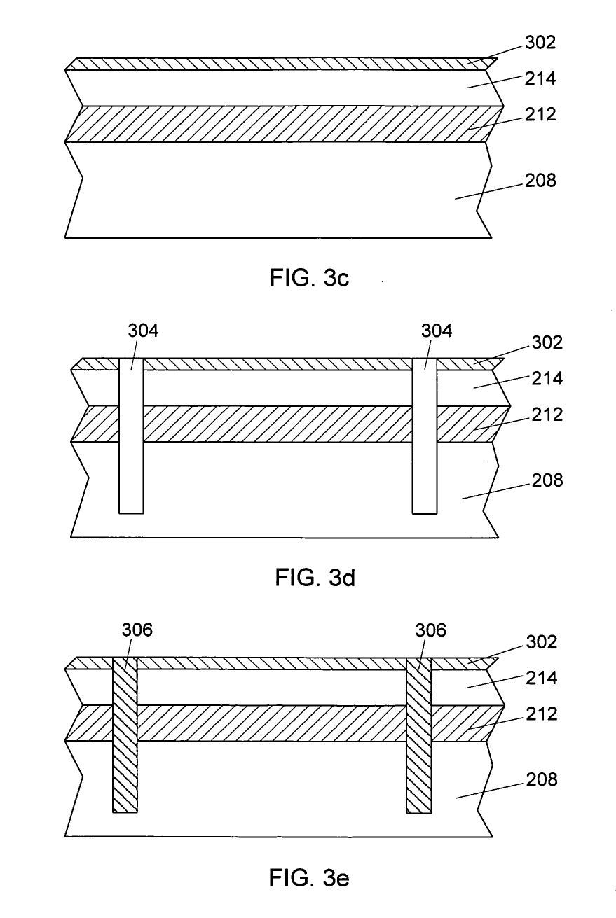

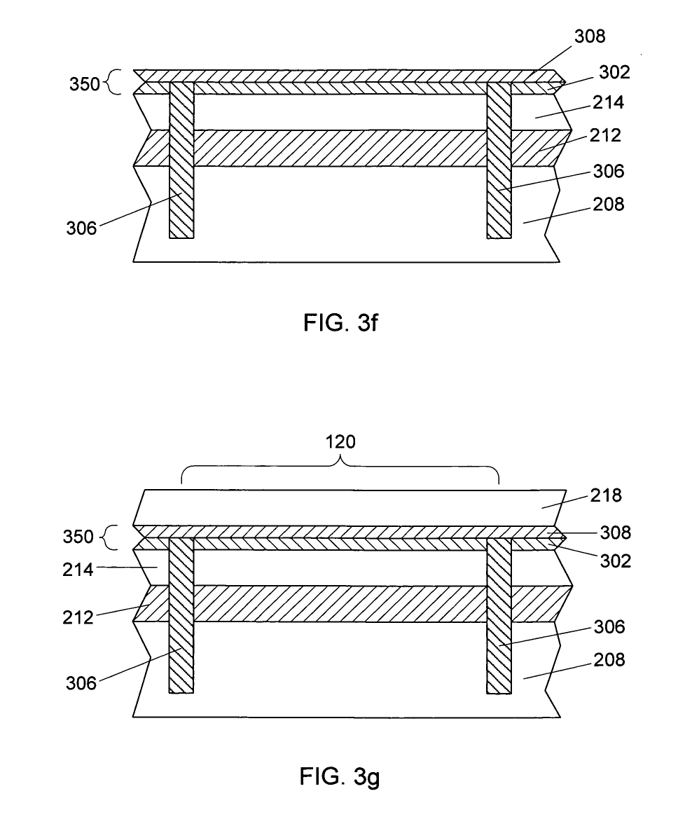

Embodiments of the fabrication of the memory cells 120 in the wordline direction 130 (see FIG. 1) are illustrated in side cross-sectional views in FIGS. 3a-3g, 4a, 4b, 5a-5f, 6a-6d, and 7.

In an embodiment, as shown in FIG. 3a, the tunnel dielectric layer 212 is formed adjacent a substrate 208, and a charge storage layer 214 formed adjacent the tunnel dielectric layer 212. The microelectronic substrate 208 may be any applicable substrate, including, but not limited to a silicon wafer, a germanium silicon wafer, a gallium arsenide wafer, and the like.

In one embodiment of the present disclosure, the tunnel dielectric layer 212 may comprise single layer of dielectric material, including, but not limited to, silicon oxide (SiO₂) or silicon oxynitride (SiON). In another embodiment, the tunnel dielectric layer 212 may comprise multiple layer structure. In a bi-layer embodiment, the tunnel dielectric layer 212 may comprise a layer of silicon dioxide and a layer of silicon oxynitride or may comprise a layer of silicon dioxide and a layer of silicon nitride (Si₃N₄). In a tri-layer embodiment, the tunnel dielectric layer 212 may comprise a layer of silicon nitride between two layers of silicon dioxide and/or may comprise a layer of silicon oxynitride between two layers of silicon dioxide. In an embodiment of the present disclosure, the tunnel dielectric layer 212 may have a thickness of between about 4 and 9 nm. The formation of the tunnel dielectric layer 212 may comprise depositing the dielectric material(s), including, but limited to chemical vapor deposition, physical vapor deposition, and/or atomic layer deposition, or growing the dielectric on the substrate 208, as will be understood to those skilled in the art.

In one embodiment of the present disclosure, the charge storage layer 214 may comprise continuous conductors of electrically conductive or semi-conductive materials, including but not limited to silicon, metals, metal alloys, and conductive metal nitrides and oxides (such as tantalum nitride (TaN) or ruthenium dioxide (RuO₂)). In another embodiment, the charge storage layer 214 may comprise discontinuous conductors of electrically conductive or semi-conductive materials, including but not limited to the materials discussed for the continuous conductors. In yet another embodiment, the charge storage layer 214 may comprise a continuous dielectric materials (charge trapping), including but not limited to silicon nitride, silicon oxynitride, and the like. In an embodiment, the charge storage layer 214 may have a thickness of between about 1 and 10 nm. In specific embodiment, shown in FIG. 3b, the charge storage layer 214 may comprise multiple layers 214₁, 214₂ and 214₃ and in a more specific embodiment at least one of the multiple layers 214₁, 214₂ and 214₃ is a conductive material. The formation of the charge storage layer 214 may comprise depositing the appropriate material by any technique known in the art, including, but limited to chemical vapor deposition, physical vapor deposition, and/or atomic layer deposition.

As shown in FIG. 3c, a first blocking dielectric layer 302 may be formed adjacent the charge storage layer 214. The first blocking dielectric layer 302 may comprise any appropriate dielectric material, including but not limited to silicon dioxide (SiO₂), silicon oxynitride (SiOₓN_{y}), silicon nitride (SiₓN_{y}), and high K dielectric materials. High K dielectric materials (e.g., materials with a dielectric constant greater than silicon oxide) may include, but are not limited to hafnium oxide (HfO₂), hafnium aluminum oxide (HfₓAl_{y}O_{z}), hafnium silicon oxide (HfₓSi_{y}O_{z}), zirconium oxide (ZrO₂), zirconium silicon oxide (ZrₓSi_{y}O_{z}), zirconium aluminum oxide (ZrₓAl_{y}O_{z}), aluminum oxide (Al₂O₃), and lanthanide series silicates, oxides, or aluminates, where x, y, and z represent suitable quantities of the respective elements. In a specific embodiment, the first blocking dielectric layer 302 may comprise hafnium silicon oxide, hafnium oxide, zirconium silicon oxide, or zirconium oxide. In another specific embodiment, the first blocking dielectric layer 302 may comprise a high K dielectric material having a dielectric constant of great than about 10.

As shown in FIG. 3d, at least one trench 304 may be formed through the first blocking dielectric layer 302, through the charge storage layer 214, through the tunnel dielectric layer 212, and into the substrate 208. By removing a portion of the first blocking dielectric layer 302 to form the trench(es) 304, the first blocking dielectric layer 302 becomes isolated from adjacent memory cells 120 in the wordline direction 130, e.g., between the memory cell strings 104₁, 104₂, . . . , and 104_{X} (see FIG. 1). Additionally, the trench 304 also isolates the charge storage layer 214 and the substrate 208 material in the wordline direction 130, e.g. between the memory cell strings 104₁, 104₂, . . . , and 104_{X} (see FIG. 1).

The trenches 304 of the various embodiments of the present description may be formed by any suitable method including laser ablation, ion ablation, lithography, and/or etch processes to selectively remove material.

As shown in FIG. 3e, an isolation dielectric may be disposed in the trench(es) 304 to form an isolation trench 306. The isolation dielectric may be any appropriate dielectric material, including but not limited to the materials described for the first blocking dielectric layer 302. In one embodiment, the isolation dielectric is silicon oxide.

As shown in FIG. 3f, a second blocking dielectric layer 308 may be formed adjacent the first blocking dielectric layer 302. The second blocking dielectric layer 308 may be any appropriate dielectric, including those discussed for first blocking dielectric layer 302. In one embodiment, the formation of the isolation dielectric disposes a layer of isolation dielectric material adjacent the first blocking dielectric layer 302 to become the second blocking dielectric layer 308, thereby forming a multilayer blocking dielectric 350. In a specific embodiment, the second blocking dielectric layer 308 is silicon oxide.

In one embodiment shown in FIG. 3g, a control gate 218 may be formed in the wordline direction 130 (see FIG. 1) on the second blocking dielectric layer 308 to form the memory cell 120. The control gate 218 may be composed of a polysilicon or any suitable metal such as tantalum nitride (TaN), tantalum carbide nitride (TaCN), titanium nitride (TiN), tungsten nitride (WN), ruthenium dioxide (RuO₂), and the like, and may extend between adjacent memory cells in the wordline direction 130 (see FIG. 1). The formation of the control gate 218 may comprise depositing the appropriate material by any technique known in the art, including, but limited to chemical vapor deposition, physical vapor deposition, and/or atomic layer deposition.

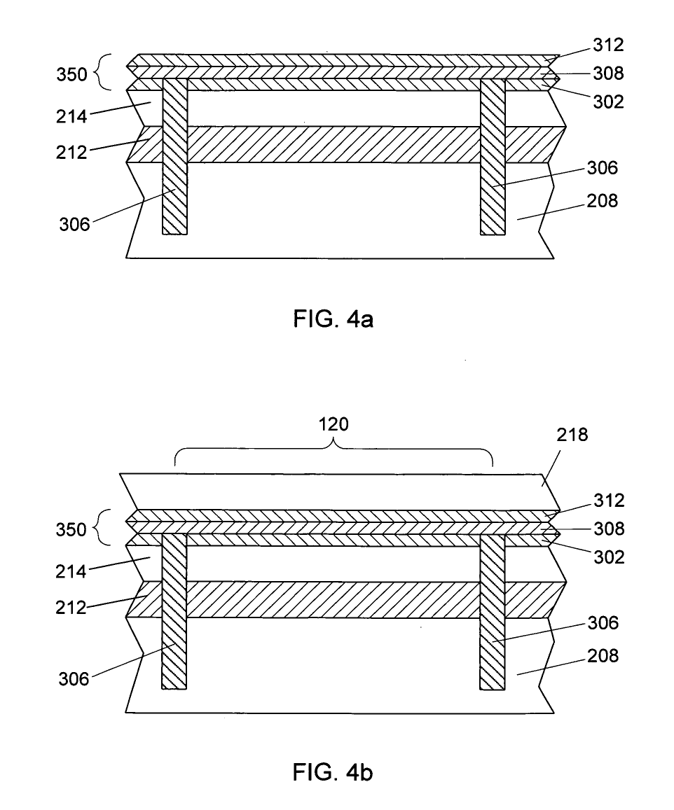

In other embodiment, referring back to FIG. 3f, a third blocking dielectric layer 312 may be formed adjacent the second blocking dielectric layer 308 to form the multilayer blocking dielectric 350, as shown in FIG. 4a. The third blocking dielectric layer 312 may be any appropriate dielectric, including those discussed for first blocking dielectric layer 302. In a specific embodiment, the third blocking dielectric layer 312 may comprise hafnium silicon oxide, hafnium oxide, zirconium silicon oxide, or zirconium oxide. The control gate 218 may be formed in the wordline direction 130 (see FIG. 1) adjacent the third blocking dielectric layer 312 to form the memory cell 120, as shown in FIG. 4b. Additionally, it is understood, that addition dielectric layers may be formed before forming the control gate 218.

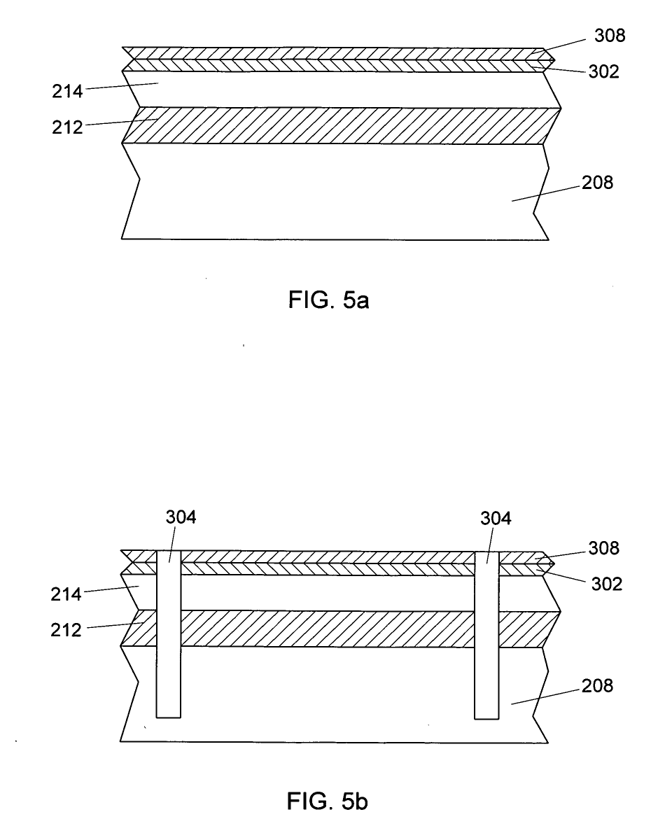

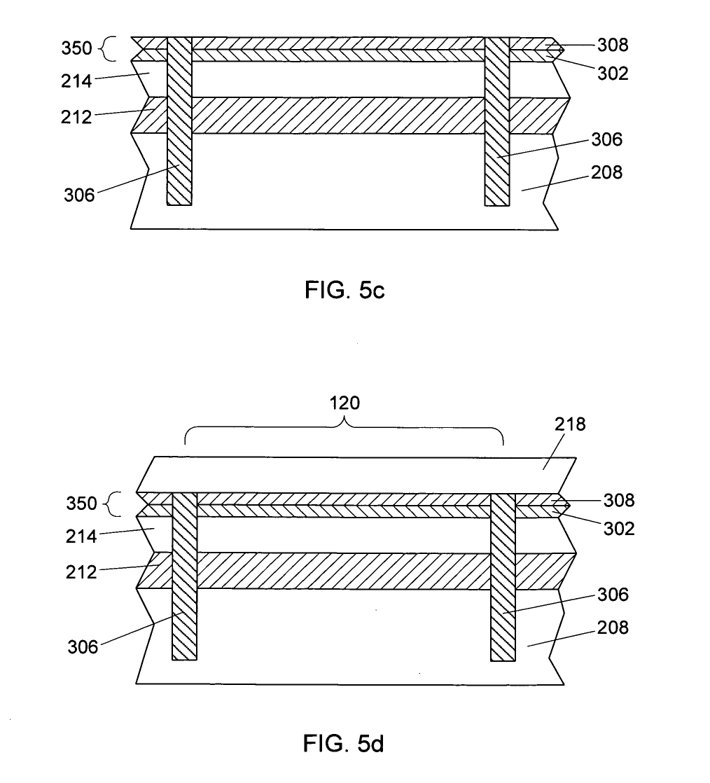

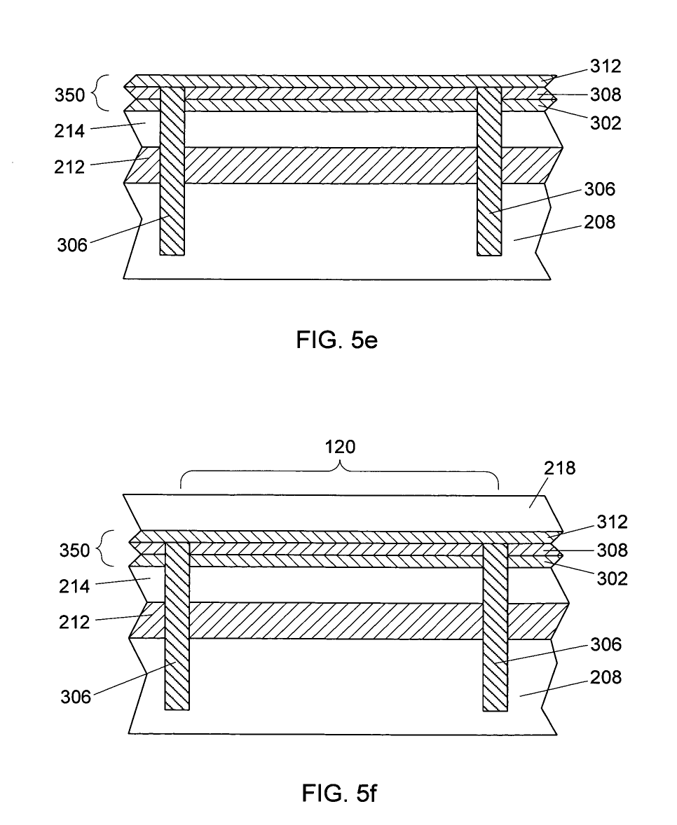

In another embodiment, referring back to FIG. 3b, the second blocking dielectric layer 308 is formed adjacent the first blocking dielectric layer 302, as shown in FIG. 5a. As shown in FIG. 5b, at least one trench 304 may be formed through the second blocking dielectric layer 308, the first blocking dielectric layer 302, through the charge storage layer 214, through the tunnel dielectric layer 212, and into the substrate 208. As shown in FIG. 5c, an isolation dielectric may be disposed in the trench(es) 304 to form an isolation trench 306. In one embodiment, the formation of the isolation dielectric disposes a layer of isolation dielectric material adjacent the first blocking dielectric layer 302 to become the third blocking dielectric layer 312, thereby forming a multilayer blocking dielectric 350. The control gate 218 may be formed in the wordline direction 130 (see FIG. 1) adjacent the second blocking dielectric layer 308 to form the memory cell 120, as shown in FIG. 5d. In another embodiment, a third blocking dielectric layer 312 may be formed, as shown in FIG. 5e, and a control gate 218 formed thereon to form the memory cell 120, as shown FIG. 5f. Additionally, it is understood, that addition dielectric layers may be formed before forming the control gate 218.

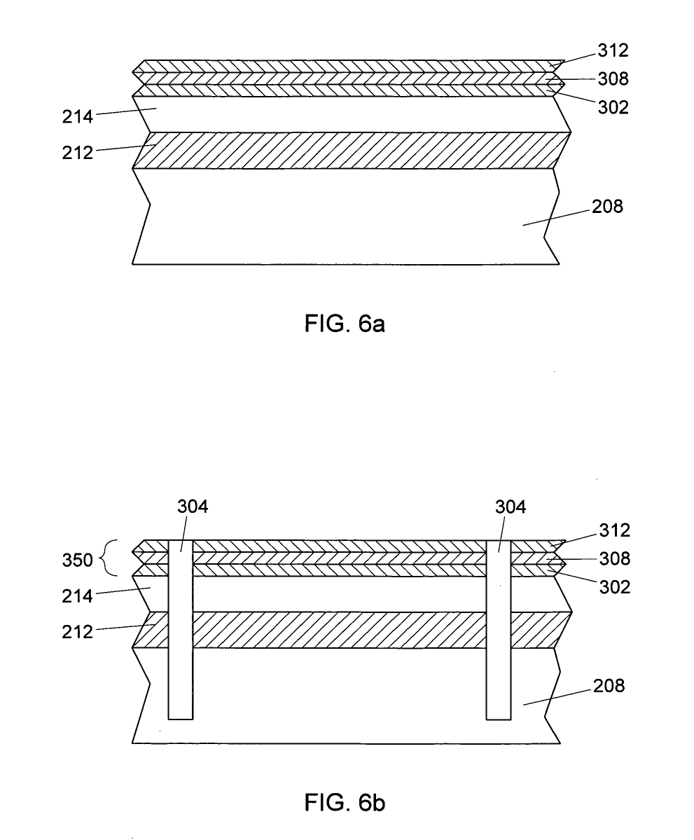

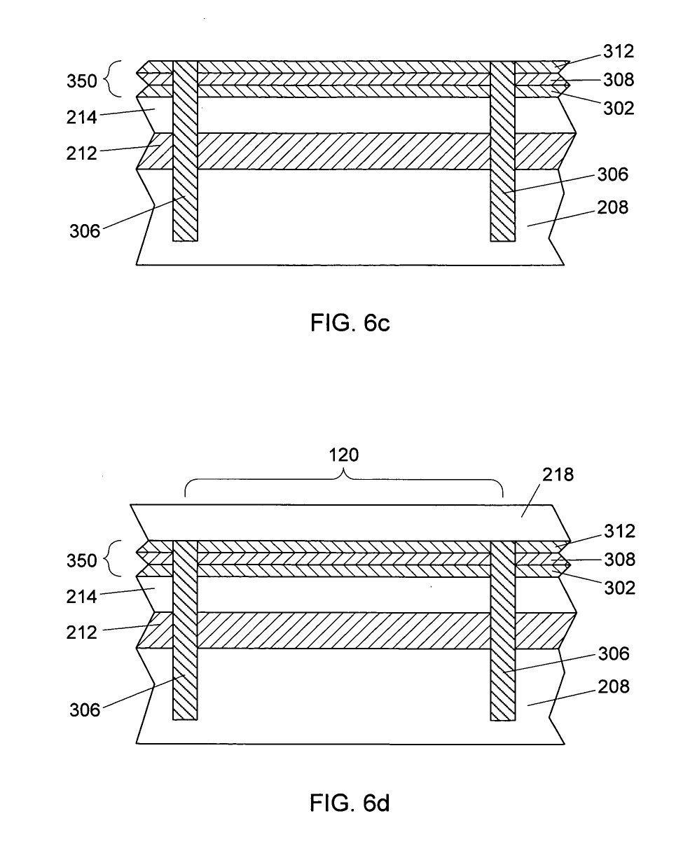

In another embodiment, referring back to FIG. 5a, the third blocking dielectric layer 312 may be formed adjacent the second blocking dielectric layer 308, as shown in FIG. 6a. As shown in FIG. 6b, at least one trench 304 may be formed through the third blocking dielectric layer 312, the second blocking dielectric layer 308, the first blocking dielectric layer 302, through the charge storage layer 214, through the tunnel dielectric layer 212, and into the substrate 208. As shown in FIG. 6c, an isolation dielectric may be disposed in the trench(es) 304 to form an isolation trench 306. The control gate 218 may be formed in the wordline direction 130 (see FIG. 1) adjacent the third blocking dielectric layer 312 to form the memory cell 120, as shown in FIG. 6d. Additionally, it is understood, that additional dielectric layers may be formed before forming the control gate 218.

The various embodiments described herein wherein, where memory cells are formed with a portion of the blocking dielectric removed in the wordline direction, may give rise to advantages in change retention and may reduce parasitic coupling interference between adjacent cells in the wordline direction.

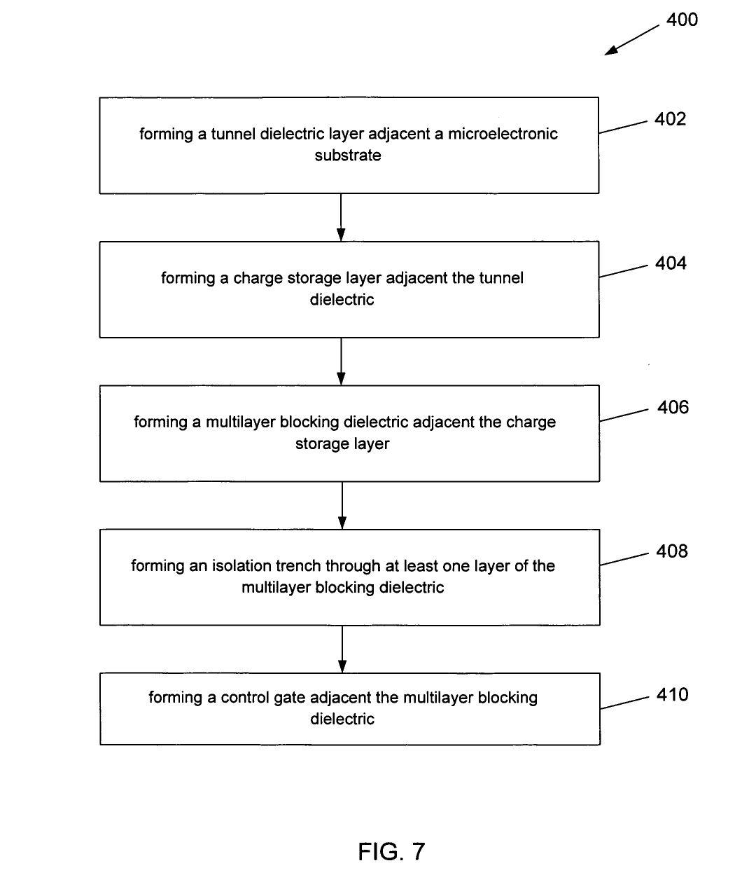

FIG. 7 is a process flow diagram of a method for forming a memory cell comprising a partially removed blocking dielectric in the wordline direction, as described herein, according to but one embodiment. In an embodiment, method 400 comprises forming a tunnel dielectric layer on a microelectronic substrate at box 402; forming a charge storage layer adjacent the tunnel dielectric at box 404; forming a multilayer blocking dielectric adjacent the charge storage layer at box 406; forming an isolation trench through at least one layer of the multilayer blocking dielectric 408; and forming a control gate adjacent the multilayer blocking dielectric at box 410.

Although the method of fabricating a memory cell 120 are described succinctly herein, it is understood that the steps for fabrication may further include other microelectronic fabrication processes such as lithography, etch, thin films deposition, planarization (such as chemical mechanical polishing (CMP)), diffusion, metrology, the use of sacrificial layers, the use of etch stop layers, the use of planarization stop layers, and/or any other associated action with microelectronic component fabrication.

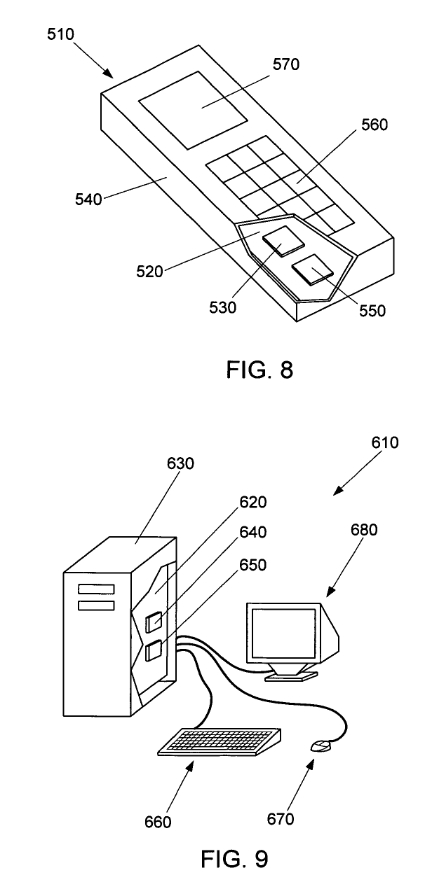

FIG. 8 illustrates an embodiment of a portable device 510, such as a cellular telephone or a personal data assistant (PDA), digital media player, of the like. The portable device 510 may comprise a substrate 520 within a housing 530. The substrate 520 may have various electronic components electrically coupled thereto including a microprocessor 540, such as a central processing units (CPUs), chipsets, graphics processor, ASICs, or other command/data processing device, and including at least one memory device 550 having at least one memory cell having a fully or partially removed blocking layer portion as described in the present description. The substrate 520 may be attached to various peripheral devices including an input device, such as keypad 560, and a display device, such an LCD display 570.

FIG. 9 illustrates an embodiment of a computer system 610. The computer system 610 may comprise a substrate or motherboard 620 within a housing 630. The motherboard 620 may have various electronic component electrically coupled thereto including a microprocessor 640, such as a central processing units (CPUs), chipsets, graphics processor, ASICs, or other command/data processing device, and at least one memory device 650, including but not limited to, a BIOS chip, a solid state drive, and the like, having at least one microelectronic cell having a fully or partially removed blocking layer portion in the wordline direction, as described above. The substrate or motherboard 620 may be attached to various peripheral devices including inputs devices, such as a keyboard 660 and/or a mouse 670, and a display device, such as a monitor 680.

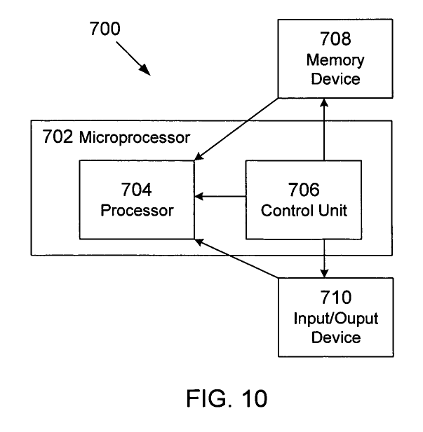

FIG. 10 illustrates a block diagram of an electronic system 700. The electronic system 700 can correspond to, for example, the portable system 510 of FIG. 8, the computer system 610 of FIG. 9, a process control system, or any other system that utilizes a processor and an associated memory. The electronic system 700 may have a microprocessor 702 (having a processor 704 and control unit 706), a memory device 708, and an input/output device 710 (it is, of course, understood that the electronic system 700 can have a plurality of processors, control units, memory device units and/or input/output devices in various embodiments). In one embodiment, the electronic system 700 may have a set of instructions that define operations which are to be performed on data by the processor 704, as well as, other transactions between the processor 704, the memory device 708, and the input/output device 710. The control unit 706 coordinates the operations of the processor 704, the memory device 708 and the input/output device 710 by cycling through a set of operations that cause instructions to be retrieved from the memory device 708 and executed. The memory device 708 can include flash memory having at least one microelectronic cell having a fully or partially removed blocking layer portion in the wordline direction.

The detailed description has described various embodiments of the devices and/or processes through the use of illustrations, block diagrams, flowcharts, and/or examples. Insofar as such illustrations, block diagrams, flowcharts, and/or examples contain one or more functions and/or operations, it will be understood by those skilled in the art that each function and/or operation within each illustration, block diagram, flowchart, and/or example can be implemented, individually and/or collectively, by a wide range of hardware, software, firmware, or virtually any combination thereof.

The described subject matter sometimes illustrates different components contained within, or connected with, different other components. It is understood that such illustrations are merely exemplary, and that many alternate structures can be implemented to achieve the same functionality. In a conceptual sense, any arrangement of components to achieve the same functionality is effectively “associated” such that the desired functionality is achieved. Thus, any two components herein combined to achieve a particular functionality can be seen as “associated with” each other such that the desired functionality is achieved, irrespective of structures or intermediate components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

It will be understood by those skilled in the art that terms used herein, and especially in the appended claims are generally intended as “open” terms. In general, the terms “including” or “includes” should be interpreted as “including but not limited to” or “includes but is not limited to”, respectively. Additionally, the term “having” should be interpreted as “having at least”.

The use of plural and/or singular terms within the detailed description can be translated from the plural to the singular and/or from the singular to the plural as is appropriate to the context and/or the application.

It will be further understood by those skilled in the art that if an indication of the number of elements is used in a claim, the intent for the claim to be so limited will be explicitly recited in the claim, and in the absence of such recitation no such intent is present. Additionally, if a specific number of an introduced claim recitation is explicitly recited, those skilled in the art will recognize that such recitation should typically be interpreted to mean “at least” the recited number.

The use of the terms “an embodiment,” “one embodiment,” “some embodiments,” “another embodiment,” or “other embodiments” in the specification may mean that a particular feature, structure, or characteristic described in connection with one or more embodiments may be included in at least some embodiments, but not necessarily in all embodiments. The various uses of the terms “an embodiment,” “one embodiment,” “another embodiment,” or “other embodiments” in the detailed description are not necessarily all referring to the same embodiments.

While certain exemplary techniques have been described and shown herein using various methods and systems, it should be understood by those skilled in the art that various other modifications may be made, and equivalents may be substituted, without departing from claimed subject matter or spirit thereof. Additionally, many modifications may be made to adapt a particular situation to the teachings of claimed subject matter without departing from the central concept described herein. Therefore, it is intended that claimed subject matter not be limited to the particular examples disclosed, but that such claimed subject matter also may include all implementations falling within the scope of the appended claims, and equivalents thereof.

What is claimed is:

1. A memory cell, comprising:
a tunnel dielectric layer;
a charge storage layer adjacent the tunnel dielectric;
a multilayer blocking dielectric adjacent the charge storage layer;
an isolation trench isolating at least one layer of the multilayer blocking dielectric in a wordline direction; and
a control gate adjacent the multilayer blocking dielectric.

2. The memory cell of claim 1, wherein the isolation trench isolates the charge storage layer in the wordline direction.

3. The memory cell of claim 1, wherein the isolation trench isolates all layers of the multilayer blocking dielectric in the wordline direction.

4. The memory cell of claim 1, wherein a least one layer of the multilayer blocking dielectric comprising a high K dielectric material.

5. The memory cell of claim 4, wherein the high K dielectric material has a dielectric constant of greater than about 10.

6. The memory cell of claim 1, wherein the charge storage layer comprises multiple layers, wherein at least one layer is a conductive material.

7. The memory cell of claim 1, wherein the multilayer blocking dielectric comprises three layers including:
a first blocking dielectric layer adjacent the charge storage layer comprising a hafnium oxide, hafnium silicon oxide, zirconium oxide, or zirconium silicon oxide;
a second blocking dielectric layer adjacent the first blocking dielectric layer comprising silicon oxide; and
a third blocking dielectric layer adjacent the second blocking dielectric layer comprising a hafnium oxide, hafnium silicon oxide, zirconium oxide, or zirconium silicon oxide.

8. A memory cell array, comprising:
a first memory cell string having a plurality of memory cells;
a second memory cell string adjacent the first memory cell string, having a plurality of memory cells;
wherein the first memory cell string has at least one memory cell of the plurality of memory cells that is adjacent a memory cell of the plurality of memory cells of the second memory cell, each of the first memory cell string memory cell and the second memory cell string memory cell comprises:
a tunnel dielectric layer;
a charge storage layer adjacent the tunnel dielectric;
a multilayer blocking dielectric adjacent the charge storage layer;
an isolation trench extending through at least one layer of the multilayer blocking dielectric between the first memory cell string memory cell and the second memory cell string memory cell; and
a control gate adjacent the multilayer blocking dielectric extending between the first memory cell string memory cell and the second memory cell string memory cell.

9. The memory cell array of claim 8, wherein the isolation trench extends through the charge storage layer between the first memory cell string memory cell and the second memory cell string memory cell.

10. The memory cell array of claim 8, wherein the isolation trench extends through all layers of the multilayer blocking dielectric between the first memory cell string memory cell and the second memory cell string memory cell.

11. The memory cell array of claim 8, wherein a least one layer of the multilayer blocking dielectric comprising a high K dielectric material.

12. The memory cell array of claim 11, wherein the high K dielectric material has a dielectric constant of greater than about 10.

13. The memory cell array of claim 8, wherein the charge storage layer comprises multiple layers, wherein at least one layer is a conductive material.

14. The memory cell array of claim 8, wherein the multilayer blocking dielectric comprises three layers including:
a first blocking dielectric layer adjacent the charge storage layer comprising a hafnium oxide, hafnium silicon oxide, zirconium oxide, or zirconium silicon oxide;
a second blocking dielectric layer adjacent the first blocking dielectric layer comprising silicon oxide; and
a third blocking dielectric layer adjacent the second blocking dielectric layer comprising a hafnium oxide, hafnium silicon oxide, zirconium oxide, or zirconium silicon oxide.

15. An electronic system, comprising:
a processor; and
a memory device in data communication with the processor, the memory comprising:
a plurality of memory cells;
at least some of the individual memory cells comprising:
a tunnel dielectric layer;
a charge storage layer adjacent the tunnel dielectric;
a multilayer blocking dielectric adjacent the charge storage layer;
an isolation trench isolating at least one layer of the multilayer blocking dielectric in a wordline direction; and
a control gate adjacent the multilayer blocking dielectric.

16. The electronic system of claim 15, wherein the isolation trench isolates the charge storage layer in the wordline direction.

17. The electronic system of claim 15, wherein the isolation trench isolates all layers of the multilayer blocking dielectric.

18. The electronic system of claim 15, wherein a least one layer of the multilayer blocking dielectric comprises a high K dielectric material.

19. The electronic system of claim 18, wherein the high K dielectric material has a dielectric constant of greater than about 10.

20. The electronic system of claim 15, wherein the charge storage layer comprises multiple layers, wherein at least one layer is a conductive material.
